(19) United States
(12) Patent Application Publication
(10) Pub. No.: US 2005/0262416 A1
(43) Pub. Date: Nov. 24, 2005

(54) Circuit and method for encoding data and data recorder

(76) Inventors: Miyuki Okamoto, Hashima-City (JP); Masato Fuma, Ichinomiya-City (JP); Shin'ichiro Tomisawa, Mizuho city (JP); Satoshi Noro, Anpachigun (JP); Hidemitsu Senoo, Higashi-osakacity (JP)

Correspondence Address: MCDERMOTT WILL & EMERY LLP, 600 13TH STREET, N.W., WASHINGTON, DC, 20005-3096, US

(21) Appl. No.: 11/133,430

(22) Filed: May 20, 2005

(30) Foreign Application Priority Data
May 21, 2004 (JP) 2004-152518 (P)

(51) Int. Cl. H03M 13/00

(52) U.S. Cl. 714/752

(57) ABSTRACT

To provide a data encoding circuit capable of securing real-timeness of a recording operation even in a memory of a low operation clock frequency by reducing the number of times of accessing the memory, and simultaneously reducing power consumption and memory costs. Prior to its writing in a memory (101), data from a host is input to an EDC arithmetic operation circuit (110) and a scrambling arithmetic operation circuit (111) to be processed, and then the error correction codes are added to the data written in the memory (101) from the scrambling arithmetic operation circuit (111) by a PI arithmetic operation circuit (104) and a PO arithmetic operation circuit (105). Accordingly, it is possible to omit memory access when the data is written from the host in the memory, and memory access when the data is read from the memory to the EDC arithmetic operation circuit. Thus, it is possible to reduce an operation clock frequency of the memory (101).

### BACKGROUND OF THE INVENTION

1. Field of the Invention

The present invention relates to a circuit and a method for encoding data, and a data recorder. In particular, the present invention is suitably used when error correction codes are added by product encoding of row (PI) and column (PO) directions.

2. Description of the Related Art

When data is recorded on a digital versatile disk (DVD), an error correction code is added for each ECC block. This error correction is carried out by using product codes. Error correction codes of row (PI) and column (PO) directions are added to data of one ECC block spread in the memory.

FIG. 6 shows a structure of an ECC block to which an error correction code is added. As shown in the drawing, one ECC block includes data of 208 rows and 181 columns. PO and PI codes are added in the 192nd to 208th rows and 172nd to 181st columns, respectively. Among those, the PI code is added to data of each row (data in sector), and the PO code is added to data of each column (data in sector). In other words, the PI code is calculated for the data of each row, and the PO code is calculated for each data of the column. The calculated PI and PO codes are added to their corresponding data to be stored in the memory.

The PO code corresponding to each column of a PI code area is stored in an overlapped portion of the PI and PO code areas. This is a case where processing of the PO direction is executed after processing of the PI direction. Conversely, however, even when the processing of the PI direction is executed after the processing of the PO direction, because of product code characteristics, the overlapped portion of the PI and PO code areas exhibits the same error correction operation.

FIG. 7 shows a configuration example (conventional example) of an error correction encoding circuit 100 which constitutes an ECC block by adding error correction codes to data. In the drawing, a memory 101 includes an SDRAM or the like. An EDC arithmetic operation unit 102 calculates and adds an error detection code to data. A scrambling arithmetic circuit 103 scrambles the data to which the error detection code has been added. A PI arithmetic operation circuit 104 calculates and adds an error correction code of a PI direction (row direction) to the scrambled data. A PO arithmetic operation circuit 105 calculates and adds an error correction code of a PO direction (column direction) to the scrambled data.

In the conventional error correction encoding circuit 100 shown in FIG. 7, first, after data of one ECC block is written from a host in the memory 101 (FIG. 8A), data of one sector is read by the EDC arithmetic operation circuit 102, a header containing a sector ID or the like is added, and then an error detection code (EDC) is added (FIG. 8B). Then, the data of one sector to which the error detection code has been added is scrambled by the scrambling arithmetic operation circuit 103 (FIG. 8C), and the scrambled data of one sector is subsequently written back in the memory 101.

Then, data are read line by line from the memory 101 to the PI arithmetic operation circuit 104, and a PI code is calculated for each line. The obtained PI code is added to its corresponding data to be written in the memory 101 (FIG. 8D). Then, when calculation and addition of PI codes are finished for all the lines, data are next read column by column, and a PO code is calculated for each PO code. The obtained PO code is added to its corresponding data to be written in the memory 101 (FIG. 8E). Accordingly, the ECC block shown in FIG. 6 is constituted in the memory 101.

Accordingly, after the ECC block has been constituted, data is read for each line, and output to a modulation circuit 200 (FIG. 8F). The modulation circuit 200 executes predetermined modulation to the input data to generate a recording signal. Such recording signals are sequentially recorded on a disk by an optical pickup 300.

Incidentally, in the error correction encoding circuit 100 shown in FIG. 7, when error correction encoding is carried out, access is frequently made from each circuit to the memory 101. In other words, when data of one ECC block is processed, the following process is carried out for the memory 101:
(1) data is written from the host (W);
(2) data is read by the EDC arithmetic operation circuit 102 (R);
(3) data is written by the scrambling arithmetic operation circuit 103 (W);
(4) data is read by the PI arithmetic operation circuit 104 (R);
(5) PI code is written by the PI arithmetic operation circuit 104 (W);
(6) data is read by the PO arithmetic operation circuit 105 (R);
(7) PO code is written by the PO arithmetic operation circuit 105 (W); and
(8) data is read to the modulation circuit 200 (R).

On the other hand, a relation with a DVD standard requires 11.08 Mbps as user data transfer rate during recording when data is recorded at a speed multiplied by 1. This is expressed to be 0.6925 Mword/S by a word (16 bits) unit.

In the error correction encoding circuit 100 shown in FIG. 7, assuming that access to the memory 101 is processed by 16 bits, the number of times of accessing the memory 101 shown in the process (1) to (8) is multiplied by the user data transfer rate 0.6925 Mword/S expressed by the word to obtain a frequency of an operation clock necessary for the memory access. Here, if the number of accessing times of (5) is about 0.2 since the access of (5) is for writing the PI code, and the number of accessing times of (7) is about 0.3 since the access of (7) is for writing the PO code, a clock frequency CL₁ necessary for operating the memory 101 is obtained by the following equation.
CL₁=6.5×0.6925=4.5 MHz (1)

This clock frequency is in the case of recording at a speed multiplied by 1. When the speed is multiplied by 16, a clock frequency CL₁₆ is represented by the following equation.
CL₁₆=4.5×16=72 MHz (2)
Further, when an overhead of memory access is estimated to be about 1.3 to 1.5, a clock frequency is represented by the following equation.
CL₁₆=94 to 108 MHz (3)

In reality, memory access in addition to the process (1) to (8) is required. Accordingly, an operation clock of the memory must be much higher.

However, the memory of such a high clock frequency is expensive. Thus, a cost problem occurs when the memory is mounted on a DVD recorder or the like. Additionally, the high operation clock frequency of the memory brings about a problem with an increase in power consumption of the memory. On the other hand, if the operation clock frequency of the memory is reduced, encoding is not finished in time, causing a fear of losing real-timeness of the recording operation.

JP 2001-298371 A describes a technology of reducing the number of times of accessing a memory by simultaneously performing PI and PO arithmetic operations.

### SUMMARY OF THE INVENTION

The present invention has been made to solve the problems, and an object of the present invention is to secure real-timeness of a recording operation even with a memory of a low operation clock frequency by reducing the number of times of accessing the memory, and to simultaneously allow reduction in power consumption and in memory costs.

According to a first aspect of the present invention, there is provided a data encoding circuit including: an EDC arithmetic operation unit for adding an error detection code to data; a scrambling arithmetic operation unit for scrambling the data to which the error detection code has been added by the EDC arithmetic operation unit; a PI arithmetic operation unit for adding an error correction code of a PI direction to the data scrambled by the scrambling arithmetic operation unit; a PO arithmetic operation unit for adding an error correction code of a PO direction to the data scrambled by the scrambling arithmetic operation unit; and a memory for writing/reading data in accordance with an operation clock, in which data from a host is input to the EDC arithmetic operation unit and the scrambling arithmetic operation unit to be processed before writing of the data in the memory, and then error correction codes are added to the data written from the scrambling unit in the memory by the PI arithmetic operation unit and the PO arithmetic operation unit.

According to a second aspect of the present invention, there is provided a method of encoding data, including: an EDC arithmetic operation step of adding an error detection code to data; a scrambling arithmetic operation step of scrambling the data to which the error detection code has been added in the EDC arithmetic operation step; a PI arithmetic operation step of adding an error correction code of a PI direction to the data scrambled in the scrambling arithmetic operation step; a PO arithmetic operation step of adding an error correction code of a PO direction to the data scrambled in the scrambling arithmetic operation step; a step of processing data from a host in the EDC arithmetic operation step and the scrambling arithmetic operation step; a step of writing the processed date in a memory; and a step of adding error correction codes to the data written in the memory in the PI arithmetic operation step and the PO arithmetic operation step.

According to a third aspect of the present invention, there is provided a data recorder equipped with a data encoding circuit for adding an error correction code to recorded data, the data encoding circuit including: an EDC arithmetic operation unit for adding an error detection code to data; a scrambling arithmetic operation-unit for scrambling the data to which the error detection code has been added by the EDC arithmetic operation unit; a PI arithmetic operation unit for adding an error correction code of a PI direction to the data scrambled by the scrambling arithmetic operation unit; a PO arithmetic operation unit for adding an error correction code of a PO direction to the data scrambled by the scrambling arithmetic operation unit; and a memory for writing/reading data in accordance with an operation clock, in which data from a host is input to the EDC arithmetic operation unit and the scrambling arithmetic operation unit to be processed before writing of the data in the memory, and then error correction codes are added to the data written from the scrambling unit in the memory by the PI arithmetic operation unit and the PO arithmetic operation unit.

According to each aspect of the present invention, prior to its writing in the memory, the data from the host is input to the EDC arithmetic operation unit and the scrambling arithmetic operation unit to be processed, and then the error correction codes are added to the data written in the memory from the scrambling arithmetic operation unit by the PI arithmetic operation unit and the PO arithmetic operation unit. Accordingly, it is possible to omit memory access when the data is written from the host in the memory, and memory access when the data is read from the memory to the EDC arithmetic operation unit. Thus, it is possible to reduce an operation clock frequency of the memory.

For example, if the present invention is applied to a DVD recorder, in accordance with the equations (1) to (3), in the case of a speed multiplied by 1, the operation clock frequency of the memory is represented as follows.
CL₁=4.5×0.6925=3.11 MHz
In the case of a speed multiplied by 16, the operation clock frequency is represented as follows.
CL₁₆=3.11×16=50 MHz
Further, when an overhead of memory access is estimated to be 1.3 to 1.5, the operation clock frequency is represented as follows.
CL₁₆=65 to 75 MHz

### BRIEF DESCRIPTION OF THE DRAWINGS

The above, other objects and novel features of the present invention will become more completely apparent upon reading the following embodiments in conjunction with the accompanying drawings, wherein:

FIG. 1 shows a configuration of a disk recorder according to Embodiment 1 of the present invention;

FIG. 2 is a flowchart of an error correction encoding process according to the Embodiment 1;

FIG. 3 shows a configuration of a disk recorder according to Embodiment 2 of the present invention;

FIG. 4 is a flowchart of an error correction encoding process according to the Embodiment 2;

FIG. 5A is a conceptual diagram of the error correction encoding process of the Embodiment 2;

FIG. 5B is a conceptual diagram of the error correction encoding process of the Embodiment 2;

FIG. 6 is a diagram showing a structure of an ECC block;

FIG. 7 shows a configuration of a disk recorder of a conventional example;

FIG. 8A is a conceptual diagram of an error correction encoding process of the conventional example;

FIG. 8B is a conceptual diagram of the error correction encoding process of the conventional example;

FIG. 8C is a conceptual diagram of the error correction encoding process of the conventional example;

FIG. 8D is a conceptual diagram of the error correction encoding process of the conventional example;

FIG. 8E is a conceptual diagram of the error correction encoding process of the conventional example; and

FIG. 8F is a conceptual diagram of the error correction encoding process of the conventional example.

### DETAILED DESCRIPTION OF THE PREFERRED EMBODIMENTS

The embodiments of the present invention will be described with reference to the accompanying drawings. The embodiments show configuration examples when the present invention is applied to a DVD recorder.

### Embodiment 1

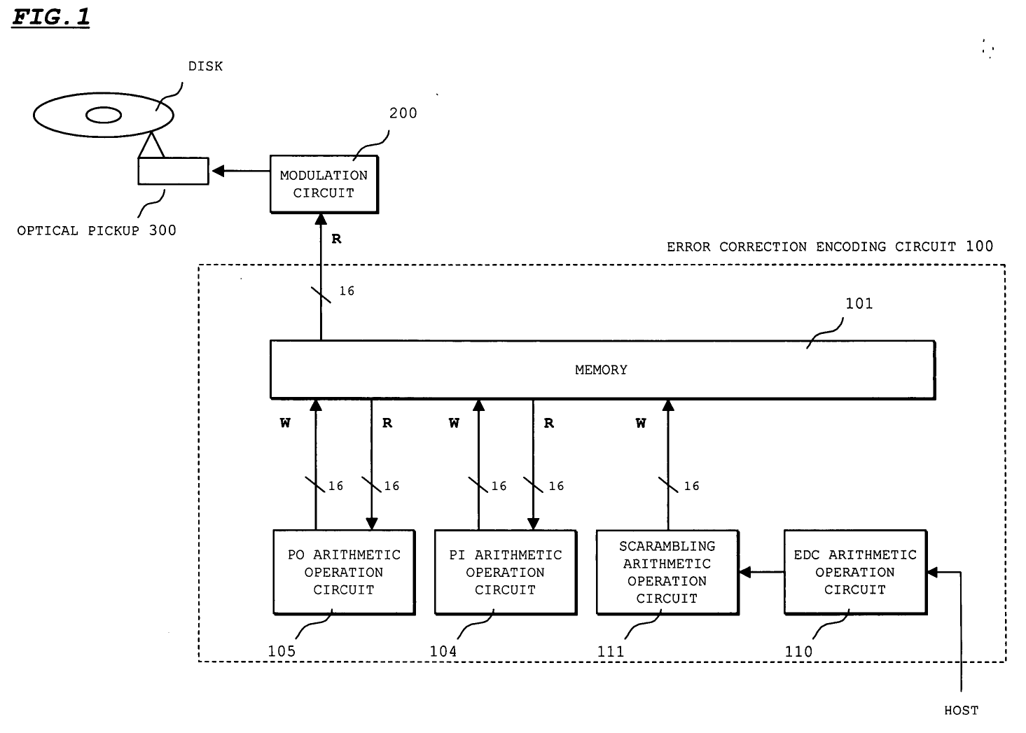

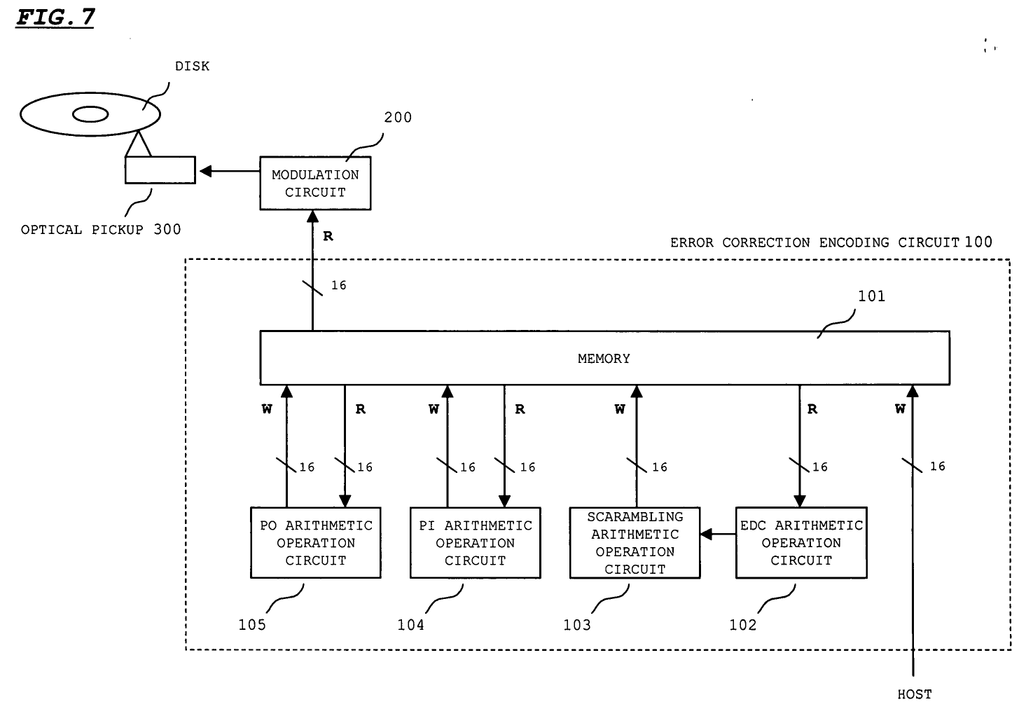

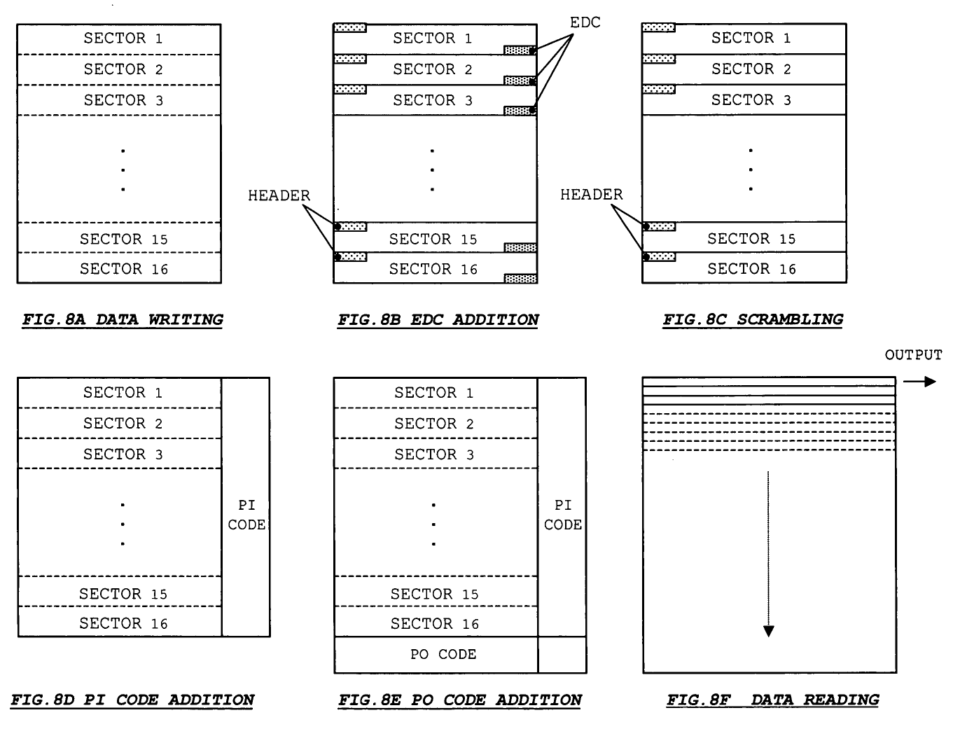

FIG. 1 shows a configuration of a disk recorder according to Embodiment 1. Portions similar to those of FIG. 7 are denoted by similar reference numerals.

A memory 101 includes an SDRAM or the like. A PI arithmetic operation circuit 104 calculates and adds an error correction code of a PI direction (row direction) to scrambled data. A PO arithmetic operation circuit 105 calculates and adds an error correction code of a PO direction (column direction) to the scrambled data. An EDC arithmetic operation circuit 110 calculates and adds an error detection code to the data. A scrambling arithmetic operation circuit 111 executes scrambling for the data to which the error detection code has been added. A modulation circuit 200 executes predetermined modulation for the input data to generate a recording signal. An optical pickup 300 applies a laser beam corresponding to the recording signal input from the modulation circuit 200 to write data in the optical disk.

According to this embodiment, recorded data is input from a host to the EDC arithmetic operation circuit 110. Each time data of one ECC block is input, the EDC arithmetic operation circuit 110 calculates and adds an error detection code to the data and outputs this data to the scrambling arithmetic operation circuit 111. The scrambling arithmetic operation circuit 111 executes scrambling on the data of one ECC block input from the EDC arithmetic operation circuit 110, and sequentially writes the data in the memory 101.

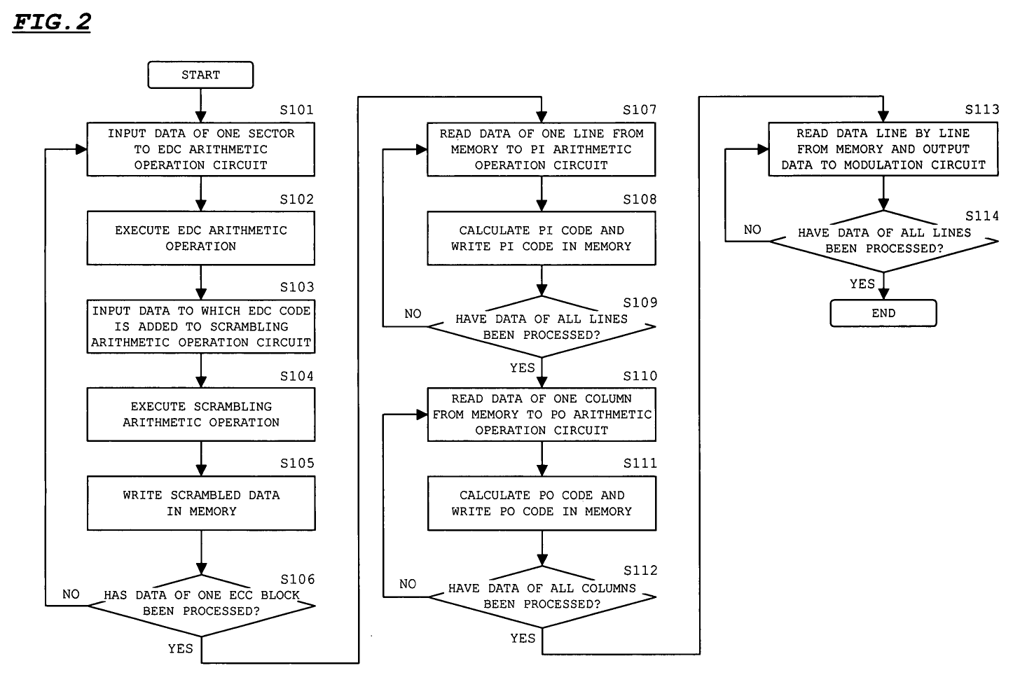

FIG. 2 is a flowchart showing an error correction encoding process for data of one ECC block.

When data of one sector (sector data) is input from the host to the EDC arithmetic operation circuit 110 (S101), a header containing a sector ID or the like is added to the sector data, followed by error detection code calculation (S102). The EDC code calculated here is added to the sector data and input to the scrambling arithmetic operation circuit 111 (S103). The scrambling arithmetic operation circuit 111 executes scrambling on the input sector data (S104). Then, the scrambled sector data is written in the memory 101 (S105). The process of steps S101 to S105 is repeated until the data of one ECC block has been written in the memory 101 (S106).

Thus, after the data of one ECC block has been written in the memory 101, then data of one line is read from the memory 101 to the PI arithmetic operation circuit 104 (S107). Then, the PI arithmetic operation circuit 104 executes on the data error correction code calculation (PI code calculation), and an obtained PI code is added to the data and written in the memory 101 (S108). This process is repeated until completion for data of all the lines (S109).

Then, data of one column is read from the memory 101 to the PO arithmetic operation circuit 105 (S110), and the PO arithmetic operation circuit 105 executes error correction code calculation (PO code calculation) on the data. An obtained PO code is added to the data and written in the memory 101 (S111). This process is repeated until completion for data of all the columns (including PI codes) (S112).

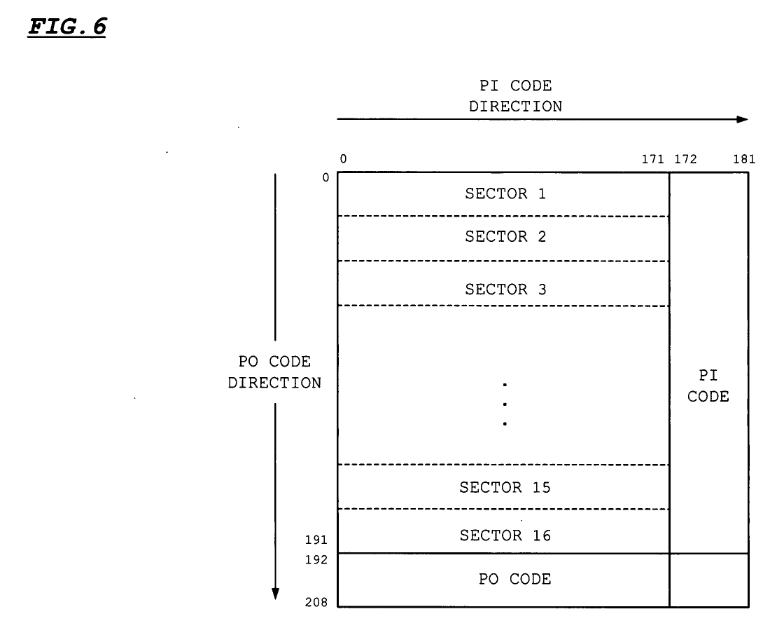

When ECC block data shown in FIG. 6 is constituted in the memory, next, data are read from the memory 101 sequentially from a head line, and output to the modulation circuit 200 (S113). The read data are sequentially modulated by the modulation circuit 200, and then recorded on the disk by the optical pickup 300. This process is repeated until completion for all the line data (S114). Thus, the data of one ECC block is recorded on the disk.

According to this embodiment, prior to its wiring in the memory 101, the data from the host is input to the EDC arithmetic operation circuit 110 and the scrambling arithmetic operation circuit 111 to be processed, and then the error correction codes are added to the data written from the scrambling arithmetic operation circuit 111 in the memory 101 by the PI arithmetic operation circuit 104 and PO arithmetic operation circuit 105. Thus, it is possible to omit memory access when the data is written from the host in the memory and memory access when the data is read from the memory to the EDC arithmetic operation circuit. As a result, it is possible to reduce an operation clock frequency of the memory 101.

### Embodiment 2

By replacing the PI arithmetic operation circuit 104 with a PI arithmetic operation circuit 112 as described below, it is possible to further reduce the number of times of accessing the memory 101.

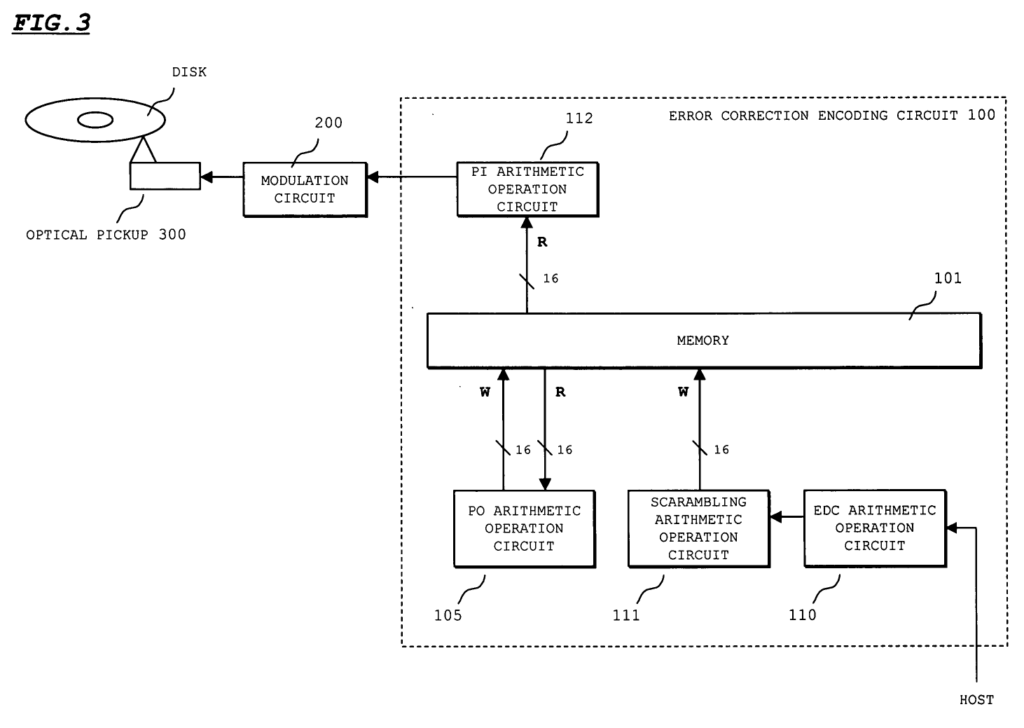

FIG. 3 shows a configuration example in this case. In this configuration example, a process of PI and PO encoding and an operation of accessing the memory 101 are different from those of the Embodiment 1. In other words, in this configuration example, processing by the PO arithmetic operation circuit 105 is first executed, then a PI code of line data is added by the PI arithmetic operation circuit 112, and the data is directly output to the modulation circuit 200.

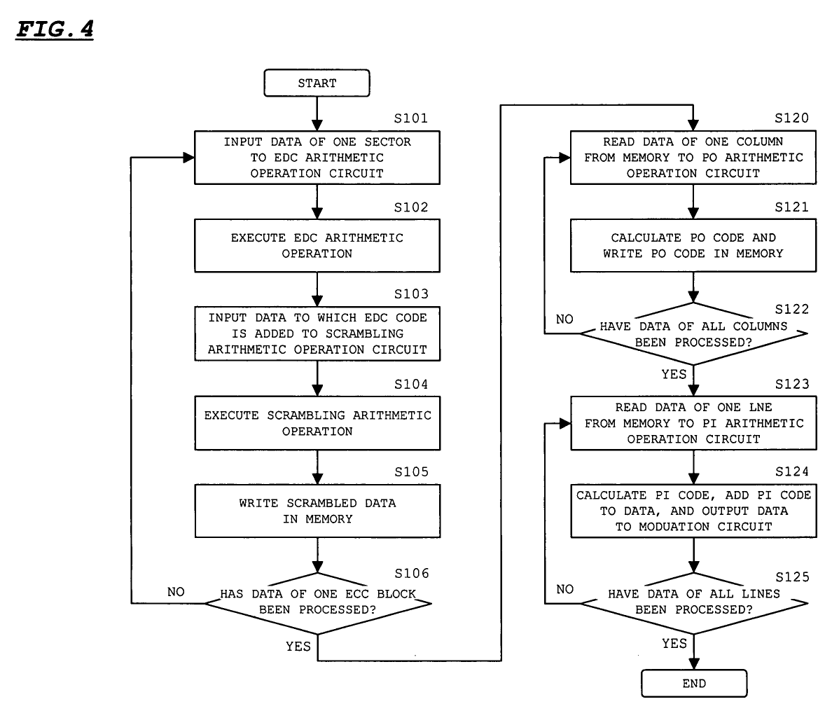

FIG. 4 is a flowchart showing an error correction encoding process for data of one ECC block. The process of steps S101 to S106 is the same as that of Embodiment 1.

In the process of steps S101 to S106, after the data of one ECC block has been written in the memory 101, data of one column is first read from the memory 101 to the PO arithmetic operation circuit 105 (S120), and then at the PO arithmetic operation circuit 105, error correction code calculation (PO code calculation) on the data is executed. An obtained PO code is added to the data and written in the memory 101 (S121). This process is repeated until completion for data of all the columns (S122).

Then, data of one line is read from the memory 101 to the PI arithmetic operation circuit 112 (S123), and the PI arithmetic operation circuit 112 executes error correction code calculation (PI code calculation) on the data. An obtained PI code is added to the data and output to the modulation circuit 200 (S124). This process is repeated until completion for data of all the lines (S125).

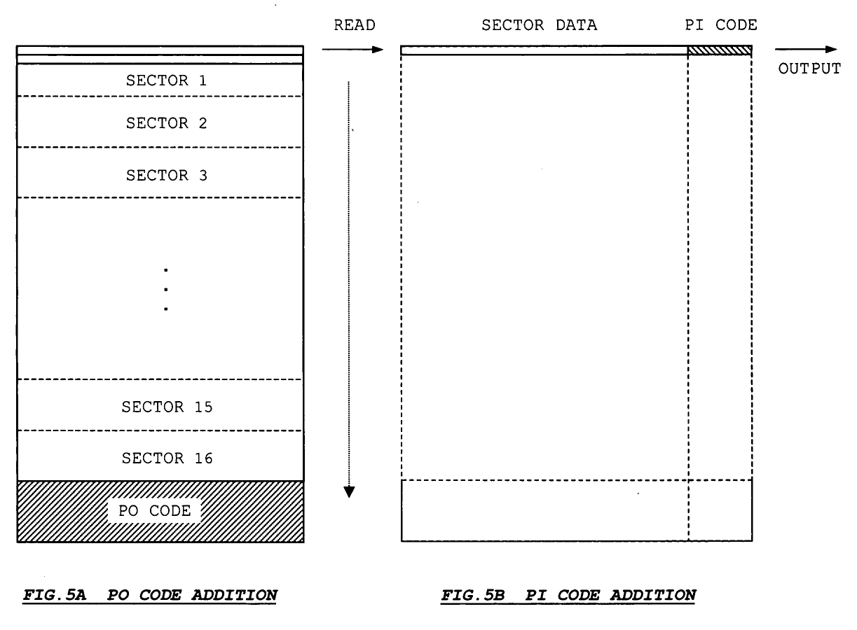

FIGS. 5A and 5B conceptually show the process of steps S123 to S125. The data constituted in the memory 101 in steps S101 to S122 (see FIG. 5A) are read sequentially from a head line, while PI codes are added to the data (see FIG. 5B). Then, the data are sequentially output to the modulation circuit 200 provided in the following stage, and recorded on the disk.

According to this embodiment, as compared with Embodiment 1, it is possible to omit memory access when the data is read from the memory 101 to the modulation circuit 200 and memory access when the error correction code of the PI direction is written from the PI arithmetic operation circuit in the memory. As a result, it is possible to further reduce an operation clock frequency of the memory 101.

In addition, since PI codes are not written in the memory, the memory capacity that would be required for the PI codes can be saved. Alternatively, a free memory area created due to the fact that the PI codes are not written in the memory can be used as a work area for another process. In an ECC block including data of the rows and columns whose numbers are shown in FIG. 6, the PI code area has a data amount approximately corresponding to that of one sector, by which the memory capacity can be saved.

Hereinabove, description has been made of the present invention with reference to the embodiments. However, the present invention is not limited to the above-mentioned embodiments. The present invention can be modified variously as appropriate within the technical thoughts described in the scope of the claims appended hereto.

1. A data encoding circuit, comprising:
an EDC arithmetic operation unit for adding an error detection code to data;
a scrambling arithmetic operation unit for scrambling the data to which the error detection code has been added by the EDC arithmetic operation unit;
a PI arithmetic operation unit for adding an error correction code of a PI direction to the data scrambled by the scrambling arithmetic operation unit;
a PO arithmetic operation unit for adding an error correction code of a PO direction to the data scrambled by the scrambling arithmetic operation unit; and
a memory for writing/reading data in accordance with an operation clock,
wherein data from a host is input to the EDC arithmetic operation unit and the scrambling arithmetic operation unit to be processed before writing of the data in the memory, and then error correction codes are added to the data written from the scrambling unit in the memory by the PI arithmetic operation unit and the PO arithmetic operation unit.

2. A method of encoding data, comprising:
an EDC arithmetic operation step of adding an error detection code to data;
a scrambling arithmetic operation step of scrambling the data to which the error detection code has been added in the EDC arithmetic operation step;
a PI arithmetic operation step of adding an error correction code of a PI direction to the data scrambled in the scrambling arithmetic operation step;
a PO arithmetic operation step of adding an error correction code of a PO direction to the data scrambled in the scrambling arithmetic operation step;
a step of processing data from a host in the EDC arithmetic operation step and the scrambling arithmetic operation step;
a step of writing the processed date in a memory; and
a step of adding error correction codes to the data written in the memory in the PI arithmetic operation step and the PO arithmetic operation step.

3. A data recorder equipped with a data encoding circuit for adding an error correction code to recorded data, the data encoding circuit comprising:
an EDC arithmetic operation unit for adding an error detection code to data;
a scrambling arithmetic operation unit for scrambling the data to which the error detection code has been added by the EDC arithmetic operation unit;
a PI arithmetic operation unit for adding an error correction code of a PI direction to the data scrambled by the scrambling arithmetic operation unit;
a PO arithmetic operation unit for adding an error correction code of a PO direction to the data scrambled by the scrambling arithmetic operation unit; and
a memory for writing/reading data in accordance with an operation clock,
wherein data from a host is input to the EDC arithmetic operation unit and the scrambling arithmetic operation unit to be processed before writing of the data in the memory, and then error correction codes are added to the data written from the scrambling unit in the memory by the PI arithmetic operation unit and the PO arithmetic operation unit.
